(19) United States
(12) Patent Application Publication
(10) Pub. No.: US 2026/0286181 A1
(43) Pub. Date: Sep. 24, 2026

(54) POLISHING METHOD, ABRASIVE, AND SEMICONDUCTOR DEVICE

(71) Applicant: Kioxia Corporation, Tokyo (JP)

(72) Inventors: Momoka OTANI, Yokkaichi Mie (JP); Shuntaro YAMASHITA, Kuwana Mie (JP); Akifumi GAWASE, Kuwana Mie (JP)

(73) Assignee: Kioxia Corporation, Tokyo (JP)

(21) Appl. No.: 19/238,903

(22) Filed: Jun. 16, 2025

(30) Foreign Application Priority Data
Mar. 24, 2025 (JP) 2025-049123

(51) Int. Cl. C09G 1/02; C09K 3/14; H01L 21/304

(52) U.S. Cl. CPC C09G 1/02; C09K 3/1463; H10P 52/00

(57) ABSTRACT

A polishing method includes: supplying an abrasive to a semiconductor substrate provided with a polishing object with a mixture of a first substance and a second substance having chemical composition different from chemical composition of the first substance; and polishing the polishing object using the abrasive, wherein the abrasive contains: a partial dissolution solution having potential and pH that dissolve the first substance and do not dissolve the second substance; and abrasive grains dispersed in the partial dissolution solution.

### CROSS-REFERENCE TO RELATED APPLICATION

This application is based upon and claims the benefit of priority from Japanese Patent Application No. 2025-49123, filed on Mar. 24, 2025, the entire contents of which are incorporated herein by reference.

### BACKGROUND OF THE INVENTION

### Field of the Invention

The present embodiment relates to a polishing method, an abrasive, and a semiconductor device.

### Description of the Related Art

A material with a mixture of two or more substances is used in some semiconductor elements.

### BRIEF DESCRIPTION OF THE DRAWINGS

FIG. 1 is a schematic circuit diagram for illustrating a circuit configuration example of a memory cell array according to the first embodiment.

FIG. 2 is a cross-sectional schematic view for illustrating a structure example of a semiconductor memory according to the first embodiment and shows a cross-sectional view parallel to the Z-X plane.

FIG. 3 is a cross-sectional view parallel to the Y-Z plane showing a production process of a semiconductor device of the first embodiment.

FIG. 4 is a cross-sectional view parallel to the Y-Z plane showing a production process of a semiconductor device of the first embodiment.

FIG. 5 is a cross-sectional view parallel to the Y-Z plane showing a production process of a semiconductor device of the first embodiment.

FIG. 6 is a cross-sectional view parallel to the Y-Z plane showing a production process of a semiconductor device of the first embodiment.

FIG. 7 is a Pourbaix diagram as to indium according to the first embodiment.

FIG. 8 is a Pourbaix diagram as to tin according to the first embodiment.

FIG. 9 is a cross-sectional view parallel to the Y-Z plane showing a production process of a semiconductor device of the second embodiment.

FIG. 10 is a cross-sectional view parallel to the Y-Z plane showing a production process of a semiconductor device of the second embodiment.

FIG. 11 is a cross-sectional view parallel to the Y-Z plane showing a production process of a semiconductor device of the second embodiment.

FIG. 12 is a cross-sectional view parallel to the Y-Z plane showing a production process of a semiconductor device of the second embodiment.

FIG. 13 is a Pourbaix diagram as to indium according to the second embodiment.

FIG. 14 is a Pourbaix diagram as to gallium according to the second embodiment.

FIG. 15 is a Pourbaix diagram as to zinc according to the second embodiment.

### DETAILED DESCRIPTION OF THE INVENTION

Hereinafter, the present embodiment will be described with reference to the drawings. For easy understanding of the description, the same numerals or symbols will be used as much as possible to designate the same or similar components in the individual drawings, so that overlapping description will be omitted.

### First Embodiment

The configuration of a semiconductor memory according to the first embodiment will be described. Each drawing may show an X-axis, a Y-axis, and a Z-axis. The X-axis, the Y-axis, and the Z-axis form a three-dimensional orthogonal coordinate of the right-handed system. Hereinafter, the arrow direction of the X-axis is also referred to as an X-axis plus direction, and a direction opposite to the arrow is also referred to as an X-axis minus direction. The same holds true for the other axes. The Z-axis plus direction and the Z-axis minus direction are also referred to as an “upper side” and a “lower side”, respectively. Planes orthogonal to the X-axis, the Y-axis, and the Z-axis are also referred to as the Y-Z plane, the Z-X plane, and the X-Y plane, respectively. The Z-axis direction is also referred to as an “up-down direction”. The “upper side”, the “lower side”, and the “up-down direction” are terms that merely show a relative positional relationship in the drawings and are not terms that define orientation based on the vertical direction.

For easy understanding of the description, the dimensions or the like of constituents shown in each drawing may be indicated as dimensions different from the actual ones unless otherwise specified.

The term “connection” described herein includes not only physical connection but electrical connection and includes not only direct connection but indirect connection unless otherwise specified.

The term “formed on the upper side” described herein includes not only the case of being formed in contact with the upper side but the case of being formed on the upper side via an additional material unless otherwise specified. The same holds true for the term “formed on the lower side”.

A semiconductor memory 101 according to the first embodiment is OCTRAM (oxide semiconductor channel transistor RAM) and has a memory cell array.

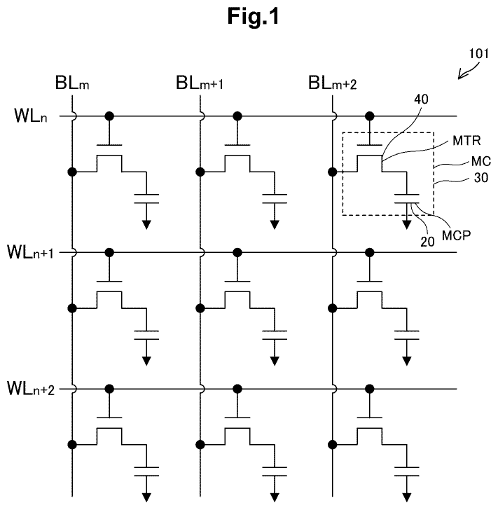

As shown in FIG. 1, the memory cell array comprises a plurality of memory cells MC, a plurality of word lines WL, and a plurality of bit lines BL.

FIG. 1 shows, as one example of the plurality of word lines WL, a word line WLₙ, a word line WLₙ₊₁, and a word line WLₙ₊₂ (wherein n is a positive integer). FIG. 1 also shows, as one example of the bit lines BL, a bit line BLₘ, a bit line BLₘ₊₁, and a bit lines BLₘ₊₂ (wherein m is a positive integer). The number of the plurality of memory cells MC is not limited to the number shown in FIG. 1.

The plurality of memory cells MC are arranged, for example, in a matrix pattern, to thereby form a memory cell array. The memory cells MC comprise a memory transistor MTR serving as a field-effect transistor (FET), and a memory capacitor MCP.

A series of memory cells MC disposed in rows are each connected to a word line WL (e.g., a word line WLₙ) corresponding to a row to which the self belongs (e.g., the n-th row). A series of memory cells MC disposed in columns are each connected to a bit line BL (e.g., a bit line BLₘ₊₂) corresponding to a column to which the self belongs (e.g., the m+2-th column).

Specifically, the gate of the memory transistor MTR contained in each memory cell MC is connected to a word line WL corresponding to a row to which the memory cell MC belongs. One of the source and the drain of the memory transistor MTR is connected to a bit line BL corresponding to a column to which the memory cells MC belongs.

One of the electrodes of the memory capacitor MCP contained in each memory cell MC is connected to the other one of the source and the drain of the memory transistor MTR contained in the memory cell MC. The other electrode of the memory cell MC is connected to a power wire (not shown) that supplies specific potential.

The memory cells MC are configured to be capable of holding data by the accumulation of charge in the memory capacitor MCP ascribable to current flowing in the corresponding bit lines BL by the switching of the memory transistor MTR based on the potential of the corresponding word lines WL.

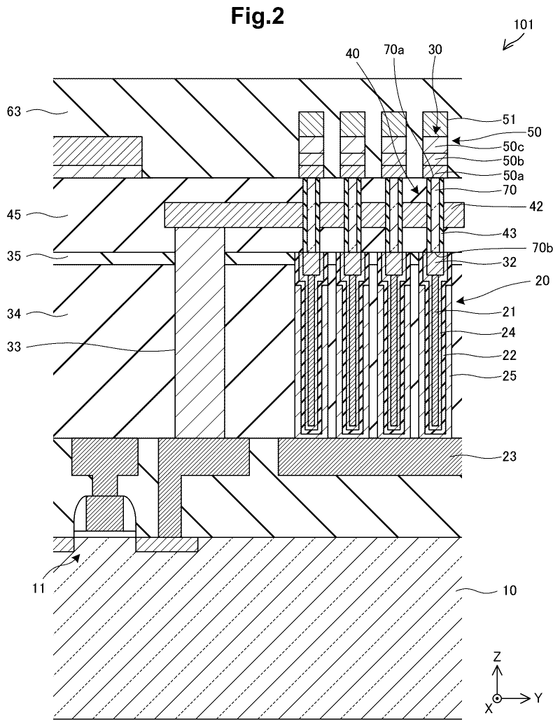

As shown in FIG. 2, the semiconductor memory 101 has a semiconductor substrate 10, a circuit 11 (one example of a “semiconductor circuit”), a capacitor 20, a semiconductor device 30, a conductor 33, and insulating layers 34, 35, and 63.

The capacitor 20 comprises a conductor 21, an insulating film 22 (one example of a “dielectric film”), a conductor 23, a capacitor electrode 24 (one example of a “first capacitor electrode”), and a capacitor electrode 25 (one example of a “second capacitor electrode”).

The semiconductor device 30 comprises a field-effect transistor 40 (one example of a “semiconductor element”), an upper electrode 50 disposed on the upper side of the field-effect transistor 40, a lower electrode 32 disposed on the lower side of the field-effect transistor 40, and a conductive layer 51.

The field-effect transistor 40 comprises an oxide semiconductor layer 70 (one example of an “oxide semiconductor”), a gate insulating film 43, a conductive layer 42 (one example of a “gate electrode”), and an insulating layer 45.

The oxide semiconductor layer 70 is formed in the insulating layer 45 and has an upper end 70a and a lower end 70b. The oxide semiconductor layer 70 is a columnar material that extends along the up-down direction. The oxide semiconductor layer 70 forms a channel of the field-effect transistor 40. The oxide semiconductor layer 70 has an amorphous structure.

The oxide semiconductor layer 70 is a semiconductor with an oxygen defect as a donor. The oxide semiconductor layer 70 comprises oxygen and at least one of indium (In), gallium (Ga), aluminum (Al), zinc (Zn), tin (Sn), titanium (Ti), tungsten (W), molybdenum (Mo), iridium (Ir), and ruthenium (Ru).

In the present embodiment, the oxide semiconductor layer 70 comprises indium, zinc, and gallium as metal elements. Specifically, the oxide semiconductor layer 70 is made of oxide of indium, gallium, and zinc, i.e., IGZO (InGaZnO). The oxide semiconductor layer 70 may be another type of oxide semiconductor.

The conductive layer 42 faces the oxide semiconductor layer 70 via the gate insulating film 43. Specifically, the conductive layer 42 functions as a gate electrode of the field-effect transistor 40 and surrounds the oxide semiconductor layer 70 via the gate insulating film 43 between the upper end 70a and the lower end 70b of the oxide semiconductor layer 70. The conductive layer 42 comprises, for example, tungsten (W).

The conductive layer 42 is a plurality of electrodes that extend substantially parallel to the Y-axis and are repetitively disposed in the X-axis direction. These electrodes correspond to the word lines WL (see FIG. 1).

The gate insulating film 43 comprises, for example, silicon and oxygen. Specifically, the gate insulating film 43 is made of silicon oxide. The gate insulating film 43 may be made of another material, for example, silicon nitride, or may be formed from two layers of a film of silicon oxide and a film of silicon nitride. The gate insulating film 43 is formed so as to cover the entire circumference of the side of the oxide semiconductor layer 70.

The upper electrode 50 is formed in the Z-axis plus direction based on the oxide semiconductor layer 70 and connected to the upper end 70a of the oxide semiconductor layer 70. The upper electrode 50 comprises a metal oxide layer 50a, a barrier metal layer 50b, and a metal film 50c.

The metal film 50c comprises tungsten. The metal oxide layer 50a is formed between the metal film 50c and the upper end 70a of the oxide semiconductor layer 70 and comprises metal oxide. The metal oxide contains, for example, indium and tin, as metal elements. In the present embodiment, the metal oxide layer 50a is formed from indium-tin-oxide (ITO).

The barrier metal layer 50b comprises titanium and nitrogen and is formed between the metal oxide layer 50a and the metal film 50c. In the present embodiment, the barrier metal layer 50b is formed from, for example, titanium nitride (TiN).

The lower electrode 32 is located in contact with the lower end 70b of the oxide semiconductor layer 70. The lower electrode 32 comprises metal oxide. Specifically, the lower electrode 32 comprises, for example, indium and tin, as metal elements. In the present embodiment, the metal oxide layer 50a is formed from indium-tin-oxide (ITO).

The metal oxide layer 50a and the lower electrode 32 may be configured to comprise at least any one element selected from indium, tin, zinc, cadmium, gold, silver, platinum, lead, copper, nickel, tungsten, and iron, without being limited to ITO.

The circuit 11 constitutes a peripheral circuit such as a decoder for selecting a predetermined memory cell MC among a plurality of memory cells MC, i.e., the capacitor 20 and the field-effect transistor 40, of the semiconductor memory 101, a sense amplifier connected to the bit lines BL, or a resistor constituted by SRAM. The circuit 11 may comprise a CMOS circuit having field-effect transistors formed by a CMOS process, i.e., a P channel-type field-effect transistor (Pch-FET) and an N channel-type field-effect transistor (Nch-FET).

The field-effect transistors of the circuit 11 may be formed using the semiconductor substrate 10, for example, a monocrystalline silicon substrate. Pch-FET and Nch-FET are so-called horizontal field-effect transistors that have a channel region, a source region, and a drain region on the semiconductor substrate 10 and have a channel for injecting a carrier in the X-axis direction or the Y-axis direction substantially parallel to the surface of the semiconductor substrate 10 in a region proximal to the surface of the semiconductor substrate 10. The semiconductor substrate 10 may have a conductive type of P type or N type. For convenience, FIG. 2 illustrates one example of the field-effect transistors of the circuit 11.

The capacitor 20 is the memory capacitor MCP contained in the memory cells MC (see FIG. 1). FIG. 2 illustrates four capacitors 20. However, the number of capacitors 20 is not limited to 4.

In the present embodiment, the capacitor 20 is disposed on the upper side of the semiconductor substrate 10. The capacitor electrode 24 in the capacitor 20 is electrically connected to the conductor 21 and the lower electrode 32. The capacitor electrode 25 faces the capacitor electrode 24. The insulating film 22 is disposed between the capacitor electrode 24 and the capacitor electrode 25.

The capacitor 20 is a three-dimensional capacitor such as a pillar capacitor. Another capacitor configured to be capable of accumulating charge may be adopted as the capacitor of the present embodiment.

The conductor 21 has a shape that abuts on an end face on the lower side of the lower electrode 32 and extends to the lower side from the end. The capacitor electrode 24 is formed so as to cover the lower electrode 32 and the conductor 21. The insulating film 22 is formed so as to cover the capacitor electrode 24. The capacitor electrode 25 surrounds a portion on the lower side of the insulating film 22 and has a lower end that abuts on an end face on the upper side of the conductor 23.

The conductor 21 can comprise a material such as amorphous silicon. The insulating film 22 may comprise a material such as hafnium oxide. The conductor 23 and the capacitor electrodes 24 and 25 may comprise a material such as tungsten (W) and titanium nitride (TiN).

The conductor 33 comprises a wire that electrically connects the circuit 11 and the semiconductor device 30. The conductor 33 may comprise a via wire and has, for example, a via wire that extends in the Z-axis direction and connects the word lines WL and the circuit 11 disposed on the semiconductor substrate 10, as shown in FIG. 2. The conductor 33 comprises, for example, copper.

The insulating layer 34 is disposed between a plurality of capacitors 20. The insulating layer 34 is, for example, a silicon oxide film containing silicon and oxygen.

The insulating layer 35 is disposed on the upper side of the insulating layer 34. The insulating layer 35 is, for example, a silicon nitride film containing silicon and nitrogen.

The semiconductor device 30 is disposed on the upper side of the capacitor 20. The field-effect transistor 40 in the semiconductor device 30 corresponds to the memory transistor MTR of the memory cells MC (see FIG. 1).

In the semiconductor device 30, the field-effect transistor 40 is disposed on the upper side of the lower electrode 32. Specifically, the oxide semiconductor layer 70 of the field-effect transistor 40 is positioned on the upper side of the lower electrode 32.

The upper electrode 50 is positioned on the upper side of the oxide semiconductor layer 70. The field-effect transistor 40 thus configured is a so-called vertical transistor having a channel that extends in the Z-axis direction (up-down direction) substantially perpendicular to the surface of the semiconductor substrate 10.

### Method for Producing Semiconductor Device

Hereinafter, a polishing method according to the first embodiment will be described. In the present embodiment, a method for producing the lower electrode 32 will be described as one example of a method for producing a semiconductor device, involving the polishing method.

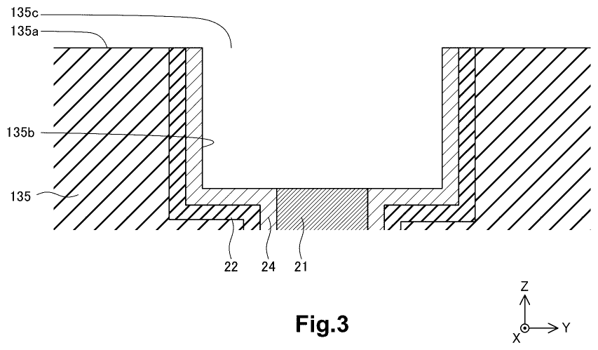

As shown in FIG. 3, a protective layer 135 is first formed on the upper side of the semiconductor substrate 10. Then, a hole 135b (one example of a “depression”) having an opening 135c is formed in a surface 135a of the protective layer 135. The protective layer 135 may be the insulating layer 35. The insulating film 22 and the capacitor electrode 24 may be disposed on the inner face of the hole 135b. The conductor 21 may be exposed to the bottom of the hole 135b.

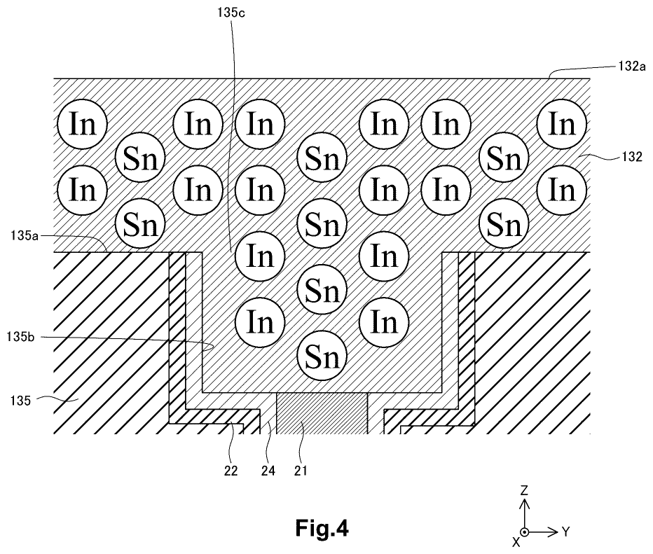

Next, as shown in FIG. 4, an oxide conductive film 132 comprising indium, tin, and oxygen is formed on the upper side of the protective layer 135. In this respect, the oxide conductive film 132 is formed so as to cover the surface 135a of the protective layer 135 while filling the hole 135b in the protective layer 135.

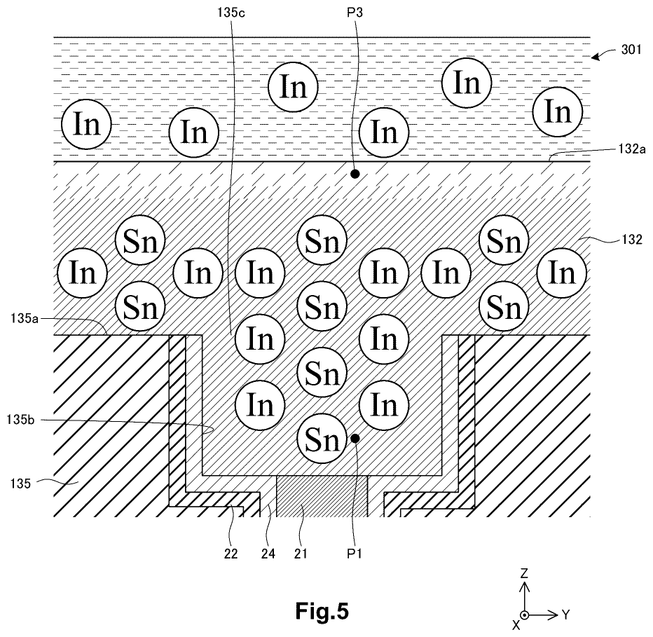

Next, as shown in FIG. 5, a slurry 301 (one example of an “abrasive”) is supplied to a surface 132a of the oxide conductive film 132 disposed on the semiconductor substrate 10. Then, a portion on the upper side of the oxide conductive film 132 is removed by a chemical mechanical polishing method (hereinafter, also referred to as a CMP method). The details of the slurry 301 will be mentioned later.

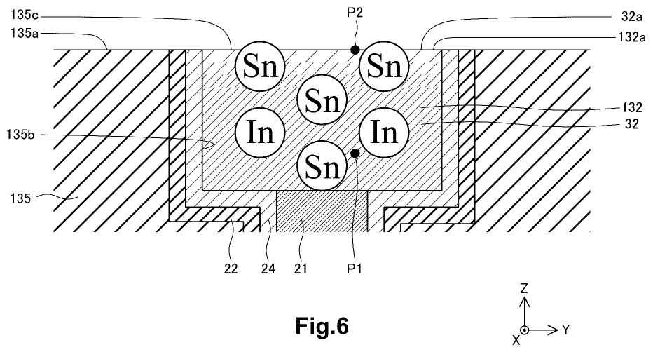

Next, as shown in FIG. 6, when the oxide conductive film 132 is polished using the slurry 301, the oxide conductive film 132 is polished until the protective layer 135 is exposed. The surface 135a of the protective layer 135 and the surface 132a of the oxide conductive film 132 sit at equal positions in the Z direction so that the surface 132a is exposed from the opening 135c of the hole 135b. The oxide conductive film 132 filled in the hole 135b serves as the lower electrode 32. Hereinafter, the surface on the upper side of the lower electrode 32 exposed from the opening 135c of the hole 135b is also referred to as an upper face 32a.

The slurry 301 is used in the polishing of a polishing object with a mixture of a first substance and a second substance having chemical composition different from chemical composition of the first substance. The first substance and the second substance are homogeneously mixed, for example.

In the present embodiment, the lower electrode 32, which is one example of the polishing object, has a mixture of indium(III) oxide (one example of the “first substance”) having chemical composition of In₂O₃, and tin(IV) oxide (one example of the “second substance”) having chemical composition of SnO₂.

The slurry 301 is also used in the polishing of a polishing object with a mixture of a first substance and a second substance containing a plurality of atoms connected through a chemical bond in a form different from that of a chemical bond that connects a plurality of atoms contained in the first substance.

In the present embodiment, the lower electrode 32, which is one example of the polishing object, has different forms of a chemical bond of the individual atoms in In₂O₃ and a chemical bond of the individual atoms in SnO₂. Specifically, a main chemical bond constituting In₂O₃ is an In—O bond. On the other hand, a main chemical bond constituting SnO₂ is an Sn—O bond.

The slurry 301 is used in the polishing of a polishing object with a mixture of a first substance which is a compound and a second substance which is a compound different from the first substance.

In the present embodiment, the lower electrode 32, which is one example of the polishing object, has a mixture of a compound In₂O₃ and a compound SnO₂.

Specifically, the first substance comprises oxygen. The second substance comprises oxygen. More specifically, the first substance comprises indium (one example of a “first metal element”). The second substance comprises tin (one example of a “second metal element”). In the present embodiment, the first substance is oxide of indium. The second substance is oxide of tin. The polishing object is ITO which is a mixture of oxide of indium and oxide of tin.

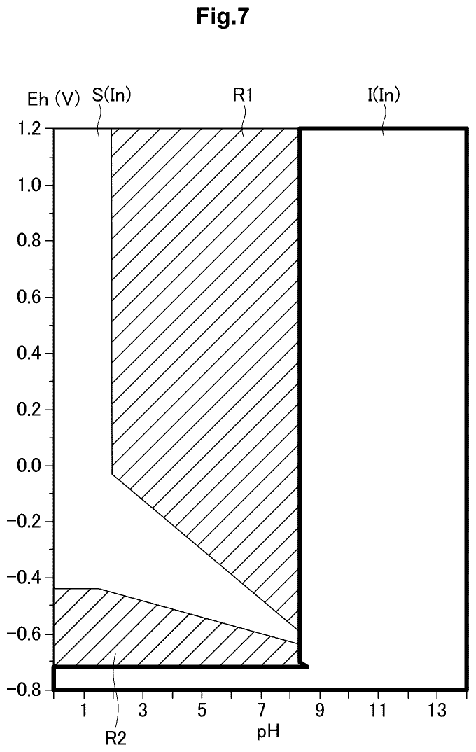

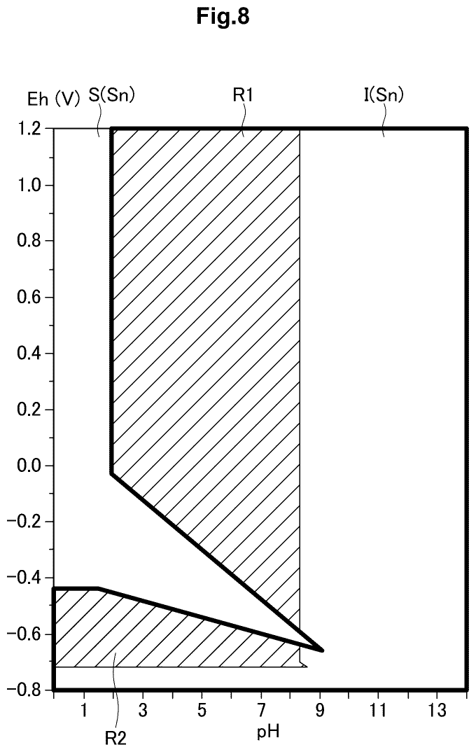

FIG. 7 is a Pourbaix diagram as to indium according to the first embodiment. FIG. 8 is a Pourbaix diagram as to tin according to the first embodiment. The ordinate depicts redox potential Eh with “V” as a unit. The abscissa depicts pH.

As shown in FIGS. 7 and 8, the Pourbaix diagram (redox potential Eh-pH diagram) illustrates the existence region of a chemical species (metal) such as indium and tin in water on a two-dimensional coordinate of electrode potential and pH. Such a Pourbaix diagram is described in “National Institute of Advanced Industrial Science and Technology Research Center for Deep Geological Environments, Naoto TAKENO, ‘Atlas of Eh-pH diagrams, Intercomparison of thermodynamic databases, Geological Survey of Japan Open File Report No.419’, pp.107, 125, 242, and 280, May 2005, URL:https://www.gsj.jp/data/openfile/no0419/openfile419e. pdf” (Hereinafter, this may be referred to as Document 1).

The Pourbaix diagram can be prepared by calculation based on thermodynamic data (theory of equilibrium). The relationship between the thermodynamic state of a metal and pH can be determined using, for example, a database such as Fact. The redox potential Eh can be determined according to, for example, the Nernst equation, on the basis of the determined thermodynamic state.

The slurry 301 comprises: a partial dissolution solution having redox potential Eh and pH that dissolve the first substance and do not dissolve the second substance; and abrasive grains dispersed in the partial dissolution solution.

Specifically, hatched regions R1 and R2 contained in the Pourbaix diagram are overlapping regions of redox potential Eh and pH ranges in which indium is soluble in water and redox potential Eh and pH ranges in which tin is insoluble in water.

More specifically, in the Pourbaix diagram as to indium (see FIG. 7), indium is insoluble when the redox potential Eh and pH of an aqueous solution are included in a region I(In) boxed in thick line. On the other hand, indium is soluble when the redox potential Eh and pH of an aqueous solution are included in a region S(In) outside the region I(In).

In the Pourbaix diagram as to tin (see FIG. 8), tin is insoluble when the redox potential Eh and pH of an aqueous solution are included in a region I(Sn) boxed in thick line. On the other hand, tin is soluble when the redox potential Eh and pH of an aqueous solution are included in a region S(Sn) outside the region I(Sn). The regions R1 and R2 are overlapping regions of the region S(In) and the region I(Sn).

The partial dissolution solution has redox potential Eh and pH included in the region R1 or R2. The partial dissolution solution comprises an oxidizing agent or a reducing agent as a solute. The redox potential Eh is adjusted, for example, by dissolving an appropriate oxidizing agent or reducing agent in the partial dissolution solution.

Specifically, the oxidizing agent has, for example, an oxoacid compound, peroxide, a bromine compound, an iron compound, ozone, silver salt, a carboxylic acid compound, acetyl acetonate, or phthalate.

More specifically, examples of the oxoacid compound include iodic acid compounds, manganic acid compounds, sulfuric acid compounds, molybdic acid compounds, nitric acid compounds, chromic acid compounds, chloric acid compounds, carbonic acid compounds, boric acid compounds, acetic acid compounds, vanadic acid compounds, ruthenic acid compounds, rhenic acid compounds, and tungstic acid compounds.

Examples of the iodic acid compounds include iodic acid, hypoiodous acid, iodate (e.g., potassium iodate), periodic acid, and periodate (e.g., potassium periodate).

Examples of the manganic acid compounds include permanganic acid and permanganate (e.g., potassium permanganate and sodium permanganate).

Examples of the sulfuric acid compounds include persulfuric acid (e.g., peroxymonosulfuric acid and peroxydisulfuric acid) and persulfate (e.g., ammonium persulfate and potassium persulfate).

Examples of the molybdic acid compounds include molybdate (e.g., ammonium molybdate).

Examples of the nitric acid compounds include nitric acid and nitrate (e.g., potassium nitrate and iron nitrate).

Examples of the chromic acid compounds include chromic acid, chromate (e.g., potassium chromate), and bichromate.

Examples of the chloric acid compounds include chloric acid, chlorate, perchloric acid, perchlorate (e.g., potassium perchlorate), chlorous acid, hypochlorous acid, and hypochlorite.

Examples of the carbonic acid compounds include percarbonic acid and percarbonate (e.g., sodium percarbonate).

Examples of the boric acid compounds include perboric acid and perborate (e.g., sodium perborate and sodium perborate monohydrate).

Examples of the acetic acid compounds include acetic acid, peracetic acid, and acetate.

Examples of the vanadic acid compounds include vanadic acid and vanadate (e.g., ammonium vanadate, sodium vanadate, and potassium vanadate).

Examples of the ruthenic acid compounds include ruthenic acid.

Examples of the molybdic acid compounds include molybdic acid and molybdate (e.g., ammonium molybdate and disodium molybdate).

Examples of the rhenic acid compounds include rhenic acid.

Examples of the tungstic acid compounds include tungstic acid and tungstate (e.g., disodium tungstate).

Examples of the peroxide include peroxides and peroxy compounds.

Examples of the peroxides include peroxide (e.g., hydrogen peroxide) and peroxide salt (e.g., sodium peroxide and barium peroxide).

Examples of the peroxy compounds include propane peroxy acid, substituted or unsubstituted butane peroxy acid, hydroperoxyacetaldehyde, potassium periodate, and ammonium peroxymonosulfate.

Examples of the bromine compound include bromine compounds including bromic acid, hypobromous acid, and bromate (e.g., potassium bromate).

Examples of the iron compound include iron compounds including ferric salt, ferric acid, ferric acid salt (e.g., potassium ferrocyanide), ferric chlorite, iron(III) salt, and iron(III) nitrite.

The ozone is, for example, ozone water. The silver salt is, for example, silver(II) salt. The carboxylic acid compound is, for example, a formic acid compound, perbenzoic acid, perphthalic acid, dichloroisocyanuric acid, dichloroisocyanurate, citrate, gluconate, oxalate, or succinate. Examples of the formic acid compound include formic acid and performic acid.

The reducing agent has, for example, an organic acidic compound, a saccharide, hydrogen peroxide, a reduced sulfur compound, or a hydrazine compound.

More specifically, examples of the organic acidic compound include organic acidic compounds. Examples of the organic acidic compounds include ascorbic acid, formic acid, oxalic acid, 3,4- and 5-trihydroxybenzoic acid, and their derivatives and salts.

The ascorbic acid includes L-ascorbic acid, D-ascorbic acid, and isoascorbic acid.

Examples of the derivatives include ascorbic acid derivatives such as alkyl glyceryl ascorbic acid, ascorbic acid glycerol, ascorbic acid alkyl ether, ascorbic acid alkyl ester, ascorbic acid sulfuric acid ester, and ascorbic acid phosphoric acid ester.

Other examples of the reducing agent except for inorganic acidic reducing agents and organic acidic reducing agents include saccharides, hydrogen peroxide, reduced sulfur compounds, and hydrazine compounds. Examples of the saccharides include fructose, glucose, and ribose. Examples of the hydrazine compound include hydrazine and hydrazide compounds.

The partial dissolution solution comprises a pH adjuster as a solute. The pH of the partial dissolution solution is adjusted, for example, by dissolving an appropriate pH adjuster in the partial dissolution solution.

In the case of adjusting the partial dissolution solution to pH smaller than 7, examples of the pH adjuster to the acidic side include nitric acid, sulfuric acid, hydrochloric acid, phosphoric acid, tartaric acid, succinic acid, citric acid, malic acid, malonic acid, various fatty acids, and various polyvalent carboxylic acids, and their combinations.

In the case of adjusting the partial dissolution solution to pH larger than 7, examples of the pH adjuster to the basic side include potassium hydroxide, sodium hydroxide, ammonium hydroxide, ammonia, tetraethylammonium hydroxide, ethylenediamine, organic quaternary ammonium hydroxide compounds, organic amine, piperazine, polyethylenimine, and modified polyethylenimine, and their combinations.

The abrasive grains to be dispersed in the partial dissolution solution comprise, for example, silicon and oxygen. Specifically, the abrasive grains may be silica (SiO₂) having a particle size of 50 nm. The abrasive grains are dispersed in a colloidal state in the partial dissolution solution to form colloidal silica.

The partial dissolution solution may further comprise a surfactant as a solute. The partial dissolution solution configured to comprise the surfactant can prevent the abrasive grains from accumulating at an interface with the protective layer 135 and polishing the interface. Specifically, when the protective layer 135 has negative zeta potential, a surfactant having retarding potential is used for improving affinity.

The surfactant can be at least any of an anionic surfactant, a cationic surfactant, and a nonionic surfactant.

The anionic surfactant has a group selected from among, for example, a sulfonic acid group, a carboxyl group, a phosphonic acid group, a sulfoxyl group, and a phosphonooxyl group.

More specifically, the anionic surfactant has a sulfonic acid group in a molecule. Examples thereof include alkylsulfonic acid, alkylbenzenesulfonic acid, and alkylnaphthalenesulfonic acid, and their salts (alkali metal salts such as sodium salt and potassium salt, and ammonium salt, etc.).

The anionic surfactant has a carboxyl group in a molecule. Examples thereof include alkylcarboxylic acid, alkylbenzenecarboxylic acid, and alkylnaphthalenecarboxylic acid, and their salts (alkali metal salts such as sodium salt and potassium salt, and ammonium salt, etc.).

The anionic surfactant has a phosphonic acid group in a molecule. Examples thereof include alkylphosphonic acid, alkylbenzenephosphonic acid, and alkylnaphthalenephosphonic acid, and their salts (alkali metal salts such as sodium salt and potassium salt, and ammonium salt, etc.).

The anionic surfactant has a sulfonic acid group or a sulfoxyl group in a molecule. Examples thereof include alkyl sulfuric acid ester, alkylbenzene sulfuric acid ester, polyoxyethylene alkyl sulfuric acid ester, polyoxyethylene alkylbenzene sulfuric acid ester, and polyoxyethylene alkylnaphthalene sulfuric acid ester, and their salts (alkali metal salts such as sodium salt and potassium salt, and ammonium salt, etc.).

The anionic surfactant mentioned above preferably has a sulfonic acid group in a molecule or a sulfoxyl group in a molecule.

More specifically, the anionic surfactant is preferably an anionic surfactant having a sulfonic acid group in a molecule, such as alkylbenzenesulfonic acid, or an anionic surfactant having a sulfoxyl group in a molecule, such as polyoxyethylene alkyl sulfuric acid ester.

A known cationic compound can be used as the cationic surfactant. Specifically, examples of the cationic surfactant include mono-long-chain alkyl-type quaternary ammonium salt and di-long-chain alkyl-type quaternary ammonium salt and their ethylene oxide adducts or propylene oxide adducts, long-chain alkyltrimethylammonium salt, long-chain alkylpyridinium salt, long-chain alkylimidazolinium salt, long-chain alkyldimethylbenzylammonium salt, and cationic polymers.

More specifically, examples of the cationic surfactant include hexadecyl trimethylammonium chloride, hexadecyl trimethylammonium bromide, octadecyl trimethylammonium chloride, octadecyl trimethylammonium bromide, stearyl trimethylammonium chloride, stearyl trimethylammonium bromide, behenyl trimethylammonium chloride, behenyl trimethylammonium bromide, cetyl trimethylammonium chloride, cetyl trimethylammonium bromide, distearyl dimethylammonium chloride, dibehenyl dimethylammonium chloride, stearyl dimethylbenzylammonium chloride, dipolyoxyethylene coconut oil alkylmethylammonium chloride, and polyoxypropylene methyldiethylammonium chloride.

The nonionic surfactant has, for example, a polyoxyethylene group or a polyoxypropylene group. Specifically, examples of the nonionic surfactant include polyoxyethylene-methylpolysiloxane copolymers, poly(oxyethylene-oxypropylene)methylpolysiloxane copolymers, polyoxyethylene alkylpolysiloxane-polyoxypropylene alkylpolysiloxane-dimethylpolysiloxane copolymers, methylpolysiloxane-alkylmethylpolysiloxane-poly(oxyethylene-oxypropylene)methylpolysiloxane copolymers, polyoxyethylene lauryl ether, and acetylene glycol polyether adducts.

### Effect

As shown in FIG. 4, the oxide conductive film 132 which is a mixture of a compound of indium (In₂O₃) and a compound of tin (SnO₂) is laminated on the upper side of the protective layer 135. In FIGS. 4 to 6, symbols with “In” and “Sn” denote compounds, not simple substances, of indium and tin, respectively.

As shown in FIG. 5, when the slurry 301 is supplied to the upper side of the oxide conductive film 132, the slurry 301 dissolves the compound of indium in the oxide conductive film 132. In short, the compound of indium is etched at a portion on the upper side of the oxide conductive film 132, whereas the compound of tin remains.

As a result, the ratio of the concentration of the compound of indium to the concentration of the compound of tin at a portion (e.g., a position P3 near the surface 132a) on the upper side of the oxide conductive film 132 is lower than the ratio of the concentration of the compound of indium to the concentration of the compound of tin at a position P1 (one example of a “first position”) closer to the bottom of the hole 135b than the position P3. In this context, the concentration may be a molar concentration.

Specifically, (the concentration of the compound of indium)/(the concentration of the compound of tin) at the position P3 is lower than (the concentration of the compound of indium)/(the concentration of the compound of tin) at the position P1. (The concentration of the compound of indium)/(the concentration of the compound of tin) may be quantified by, for example, cross-sectional EDX (energy dispersive X-ray spectroscopy) analysis.

The concentration ratios of the metal elements at the positions P1 and P3 may be compared instead of comparing the concentration ratios of the compounds at the positions P1 and P3. Specifically, (the concentration of indium)/(the concentration of tin) at the position P3 is lower than (the concentration of indium)/(the concentration of tin) at the position P1. (The concentration of indium)/(the concentration of tin) may be quantified by, for example, cross-sectional EELS (electron energy loss spectroscopy) analysis. Hereinafter, the state of the position P3 is also referred to as an indium-poor state. The state of the position P1 is also referred to as a usual concentration state.

At a portion on the upper side of the oxide conductive film 132, the compound of indium is eluted to form a thin film in which the compound of tin remains. Such a thin film becomes sparse as a whole and exhibits reduced mechanical strength. As a result, the compound of tin remaining at the portion can be easily scraped off using the abrasive grains by the chemical mechanical polishing method.

In this way, the compound of tin on the upper side of the oxide conductive film 132 is removed so that the oxide conductive film 132 in the usual concentration state comes into contact with the slurry 301. Then, the compound of indium is eluted, and mechanical strength is reduced again. The repetition of this event allows the oxide conductive film 132 to be polished by the chemical mechanical polishing method. The compound of indium is preferentially eluted over the compound of tin using the partial dissolution solution. Then, the compound of tin can be easily removed. In short, the oxide conductive film 132 can be efficiently polished by using the slurry 301 comprising the partial dissolution solution having appropriate redox potential Eh and pH and the abrasive grains dispersed in the partial dissolution solution.

The flatness of the oxide conductive film 132 thus polished by the CMP method can be improved by using the partial dissolution solution that preferentially dissolves the compound of indium. If the partial dissolution solution dissolves both the compound of indium and the compound of tin, the oxide conductive film 132 has poor flatness of the surface 132a, which is not preferred, because the oxide conductive film 132 is isotropically etched.

As shown in FIG. 6, the oxide conductive film 132 is filled into the open hole 135b in the surface 135a of the protective layer 135.

The ratio of the concentration of the compound of indium to the concentration of the compound of tin at the position P1 (one example of the “first position”) contained in the oxide semiconductor layer 70 is higher than the ratio of the concentration of the compound of indium to the concentration of the compound of tin at a position P2 (one example of a “second position”) closer to the opening 135c of the hole 135b than the position P1. The position P2 may be included in the opening 135c.

Specifically, (the concentration of the compound of indium)/(the concentration of the compound of tin) at the position P1 is higher than (the concentration of the compound of indium)/(the concentration of the compound of tin) at the position P2. (The concentration of indium)/(the concentration of tin) at the position P1 is higher than (the concentration of indium)/(the concentration of tin) at the position P2.

The position P2 thus configured to be in the indium-poor state renders ITO amorphous near the upper face 32a of the lower electrode 32 and can elevate the bond energy between a tin atom and an oxygen atom. This can increase the transfer of an oxygen atom from the oxide semiconductor layer 70 to the lower electrode 32 and can therefore increase a carrier of the oxide semiconductor layer 70 near the contact interface between the oxide semiconductor layer 70 and the lower electrode 32. The contact resistance between the oxide semiconductor layer 70 and the lower electrode 32 can thereby be reduced. Thus, a semiconductor device having good quality can be efficiently produced.

The concentration of the first substance is equal to or larger than the concentration of the second substance. In the present embodiment, the concentration of oxide of indium is equal to or larger than the concentration of oxide of tin. The lower electrode 32 can thereby be rapidly polished.

The concentration of the first substance may be smaller than the concentration of the second substance. In the present embodiment, the concentration of oxide of indium may be smaller than the concentration of oxide of tin. The corrosion of the lower electrode 32 can thereby be suppressed.

### Second Embodiment

A polishing method according to the second embodiment will be described. In the second or later embodiment, description about common items with the first embodiment will be omitted, and only different points will be described. Particularly, the same or similar working effects brought about by the same or similar configurations as those of the first embodiment will not be described below.

The polishing method according to the second embodiment differs from the polishing method according to the first embodiment in that the polishing object has three substances, and the partial dissolution solution has potential and pH that dissolve a portion of the three substances.

### Method for Producing Semiconductor Device

Hereinafter, a method for producing the oxide semiconductor layer 70 will be described as one example of a method for producing a semiconductor device, involving the polishing method according to the second embodiment.

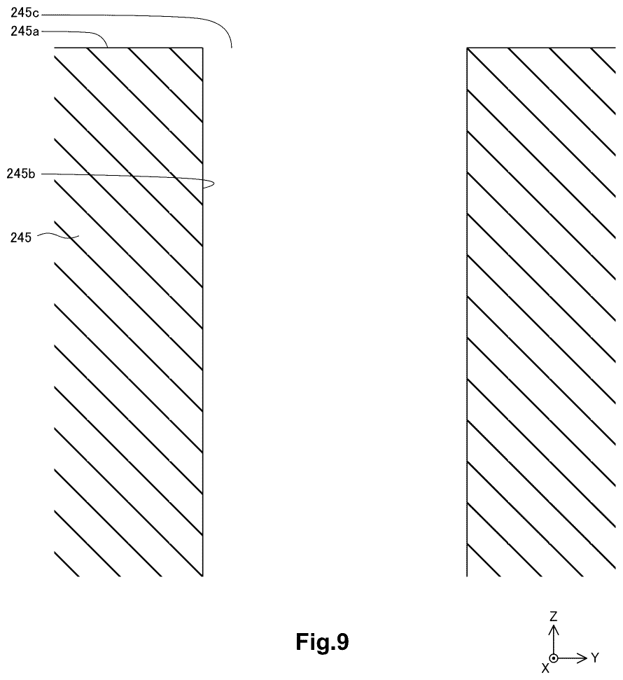

As shown in FIG. 9, a protective layer 245 is first formed on the upper side of the semiconductor substrate 10. Then, a hole 245b (one example of a “depression”) having an opening 245c is formed in a surface 245a of the protective layer 245. The protective layer 245 may be the insulating layer 45. The gate insulating film 43 (not shown) may be disposed on the inner face of the hole 245b.

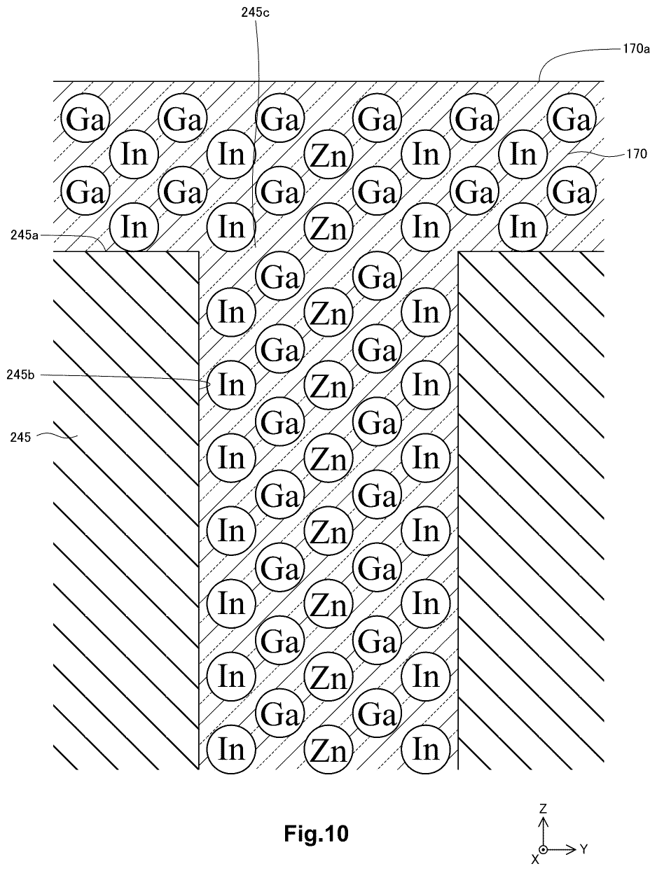

Next, as shown in FIG. 10, an oxide semiconductor layer 170 comprising indium, gallium, zinc, and oxygen is formed on the upper side of the protective layer 245. In this respect, the oxide semiconductor layer 170 is formed so as to cover the surface 245a of the protective layer 245 while filling the hole 245b in the protective layer 245.

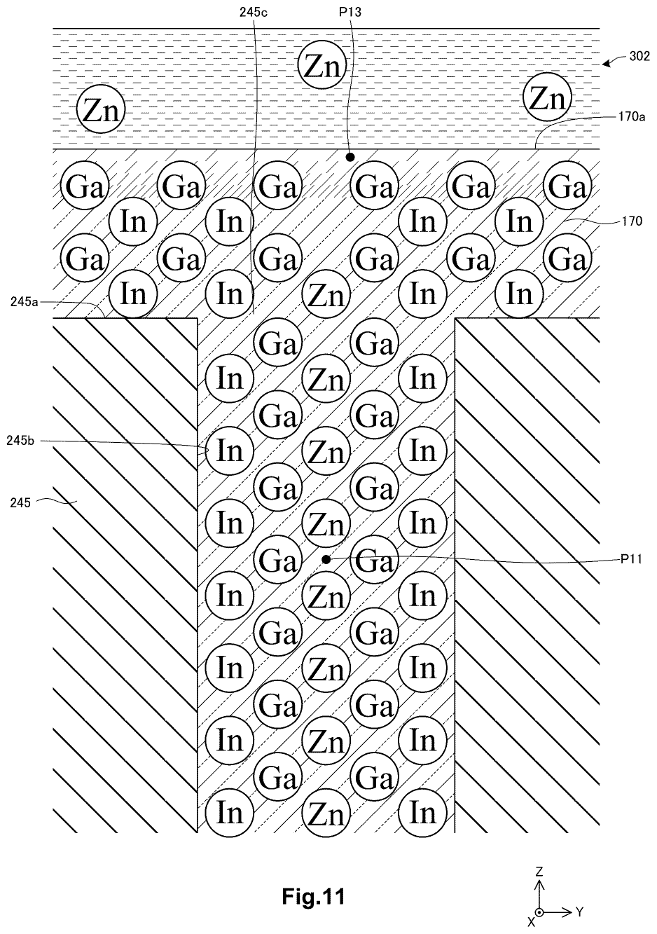

Next, as shown in FIG. 11, a slurry 302 (one example of an “abrasive”) is supplied to the surface 170a of the oxide semiconductor layer 170 disposed on the semiconductor substrate 10. Then, a portion on the upper side of the oxide semiconductor layer 170 is removed by a chemical mechanical polishing method. The details of the slurry 302 will be mentioned later.

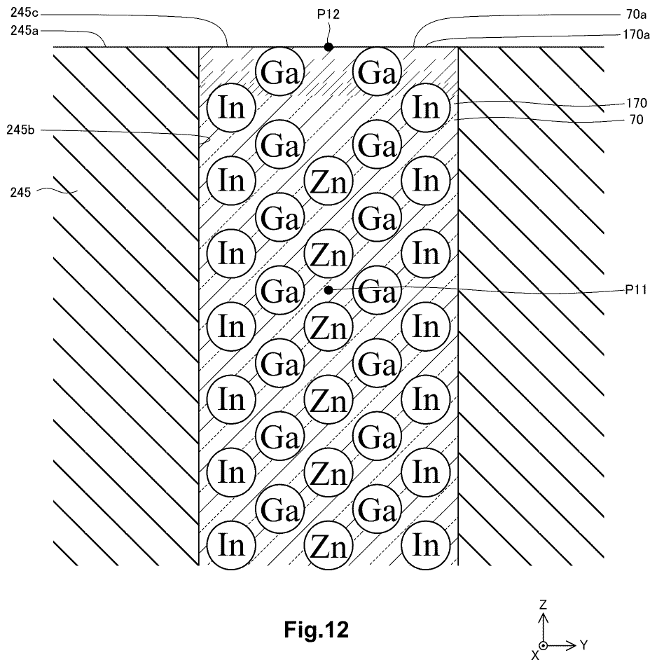

Next, as shown in FIG. 12, when the oxide semiconductor layer 170 is polished using the slurry 302, the oxide semiconductor layer 170 is polished until the protective layer 245 is exposed. The surface 245a of the protective layer 245 and the surface 170a of the oxide semiconductor layer 170 sit at equal positions in the Z direction so that the surface 170a is exposed from the opening 245c of the hole 245b. The oxide semiconductor layer 170 filled in the hole 245b serves as the oxide semiconductor layer 70.

The slurry 302 is used in the polishing of a polishing object with a mixture of a first substance, a second substance having chemical composition different from the chemical composition of the first substance, and a third substance having chemical composition different from the chemical composition of the first substance and the chemical composition the second substance. The first substance, the second substance, and the third substance are homogeneously mixed, for example.

In the present embodiment, the oxide semiconductor layer 70, which is the polishing object, has a mixture of zinc oxide (one example of the “first substance”) having chemical composition of ZnO(II), indium(III) oxide (one example of the “second substance”) having chemical composition of In₂O₃, and gallium(III) oxide (one example of the “third substance”) having chemical composition of Ga₂O₃.

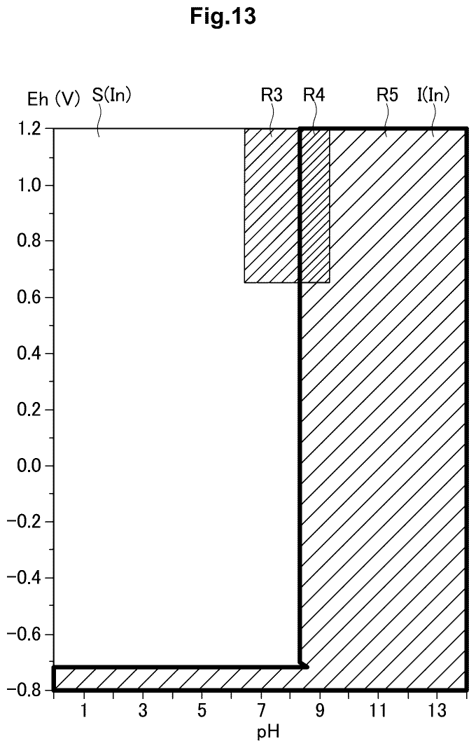

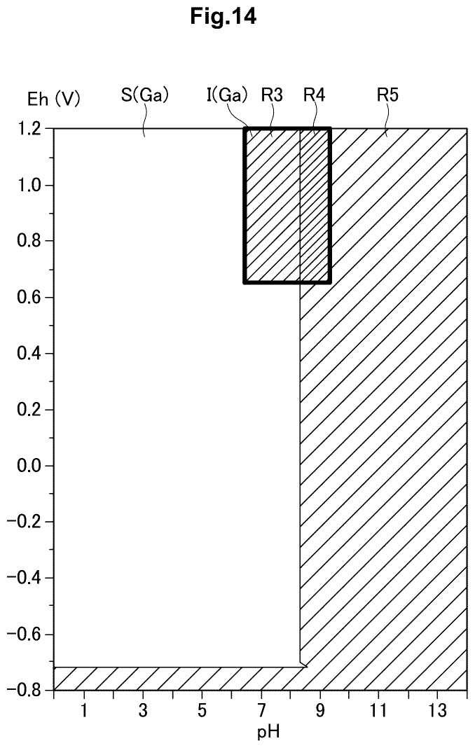

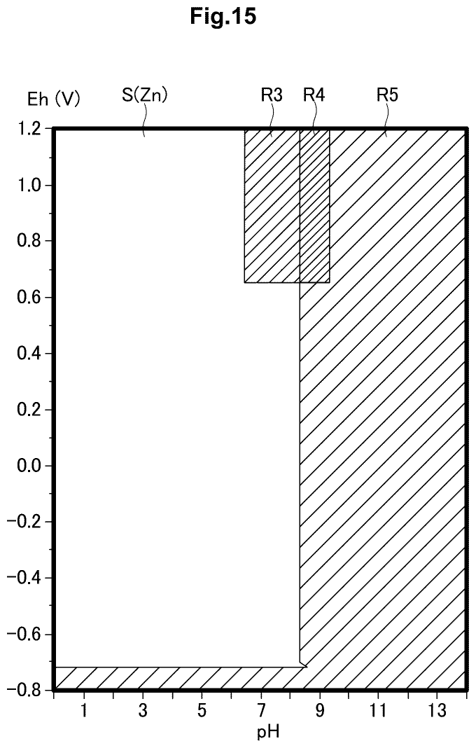

FIG. 13 is a Pourbaix diagram as to indium according to the second embodiment. FIG. 14 is a Pourbaix diagram as to gallium according to the second embodiment. FIG. 15 is a Pourbaix diagram as to zinc according to the second embodiment. Such a Pourbaix diagram is described in Document 1. The way of reading FIGS. 13 to 15 is the same as that of FIGS. 7 and 8.

As shown in FIGS. 13 to 15, the slurry 302 comprises: a partial dissolution solution having potential and pH that dissolve the first substance and dissolve neither the second substance nor the third substance; and abrasive grains dispersed in the partial dissolution solution.

Specifically, a hatched region R4 contained in the Pourbaix diagram is an overlapping region of redox potential Eh and pH ranges in which zinc is soluble in water, redox potential Eh and pH ranges in which indium is insoluble in water, and redox potential Eh and pH ranges in which gallium is insoluble in water.

More specifically, regions I(In) and S(In) in the Pourbaix diagram as to indium (see FIG. 13) are the same as the regions I(In) and S(In), respectively, shown in FIG. 7.

In the Pourbaix diagram as to gallium (see FIG. 14), gallium is insoluble when the redox potential Eh and pH of an aqueous solution are included in a region I(Ga) boxed in thick line. On the other hand, gallium is soluble when the redox potential Eh and pH of an aqueous solution are included in a region S(Ga) outside the region I(Ga).

In the Pourbaix diagram as to zinc (see FIG. 15), zinc is soluble when the redox potential Eh and pH of an aqueous solution are included in a region S(Zn) boxed in thick line. Within the redox potential Eh and pH ranges shown in FIG. 15, redox potential Eh and pH at which zinc is insoluble are absent.

The region R4 is an overlapping region of the region S(Zn), the region I(In), and the region I(Ga). The partial dissolution solution has redox potential Eh and pH included in the region R4.

### Effect

As shown in FIG. 10, the oxide semiconductor layer 170 which is a mixture of a compound of zinc (ZnO), a compound of gallium (Ga₂O₃), and a compound of indium (In₂O₃) is laminated on the upper side of the protective layer 245. In FIGS. 10 to 12, symbols with “Zn”, “Ga”, and “In” denote compounds, not simple substances, of zinc, gallium, and indium, respectively.

As shown in FIG. 11, when the slurry 302 is supplied to the upper side of the oxide semiconductor layer 170, the slurry 302 dissolves the compound of zinc in the oxide semiconductor layer 170. In short, the compound of zinc is etched at a portion on the upper side of the oxide semiconductor layer 170, whereas the compound of gallium and the compound of indium remain.

As a result, the ratio of the concentration of the compound of zinc to the concentration of the compound of indium or the compound of gallium at a portion (e.g., a position P13 near the surface 170a) on the upper side of the oxide semiconductor layer 170 is lower than the ratio of the concentration of the compound of zinc to the concentration of the compound of indium or the compound of gallium at a position P11 (one example of a “first position”) closer to the bottom of the hole 245b than the position P13.

Specifically, (the concentration of the compound of zinc)/(the concentration of the compound of indium) at the position P13 is lower than (the concentration of the compound of zinc)/(the concentration of the compound of indium) at the position P11. (The concentration of zinc)/(the concentration of indium) at the position P13 is lower than (the concentration of zinc)/(the concentration of indium) at the position P11. (The concentration of the compound of zinc)/(the concentration of the compound of gallium) at the position P13 is lower than (the concentration of the compound of zinc)/(the concentration of the compound of gallium) at the position P11. (The concentration of zinc)/(the concentration of gallium) at the position P13 is lower than (the concentration of zinc)/(the concentration of gallium) at the position P11. Hereinafter, the state of the position P13 is also referred to as a zinc-poor state. The state of the position P12 is also referred to as a usual concentration state.

At a portion on the upper side of the oxide semiconductor layer 170, the compound of zinc is eluted to form a thin film in which the compound of gallium and the compound of indium remain. Such a thin film becomes sparse as a whole and exhibits reduced mechanical strength. As a result, the compound of indium and the compound of gallium remaining at the portion can be easily scraped off using the abrasive grains by the chemical mechanical polishing method.

In this way, the compound of indium and the compound of gallium on the upper side of the oxide semiconductor layer 170 are removed so that the oxide semiconductor layer 170 in the usual concentration state comes into contact with the slurry 302. Then, the compound of zinc is eluted, and mechanical strength is reduced again. The repetition of this event allows the oxide semiconductor layer 170 to be polished by the chemical mechanical polishing method. The compound of zinc is preferentially eluted over the compound of indium and the compound of gallium using the partial dissolution solution. Then, the compound of indium and the compound of gallium can be easily removed. In short, the oxide semiconductor layer 170 can be efficiently polished by using the slurry 302 comprising the partial dissolution solution having appropriate redox potential Eh and pH and the abrasive grains dispersed in the partial dissolution solution.

The flatness of the oxide semiconductor layer 170 thus polished by the CMP method can be improved by using the partial dissolution solution that preferentially dissolves the compound of zinc. If the partial dissolution solution dissolves all the compound of zinc, the compound of indium, and the compound of gallium, the oxide semiconductor layer 170 has poor flatness of the surface 170a, which is not preferred, because the oxide semiconductor layer 170 is isotropically etched.

As shown in FIG. 12, the oxide semiconductor layer 170 is filled into the open hole 245b in the surface 245a of the protective layer 245.

The ratio of the concentration of the compound of zinc to the concentration of the compound of indium or the compound of gallium at the position P11 contained in the oxide semiconductor layer 70 is higher than the ratio of the concentration of the compound of zinc to the concentration of the compound of indium or the compound of gallium at a position P12 (one example of a “second position”) closer to the opening 245c of the hole 245b than the position P11. The position P12 may be included in the opening 245c.

Specifically, (the concentration of the compound of zinc)/(the concentration of the compound of indium) at the position P11 is higher than (the concentration of the compound of zinc)/(the concentration of the compound of indium) at the position P12. (The concentration of zinc)/(the concentration of indium) at the position P11 is higher than (the concentration of zinc)/(the concentration of indium) at the position P12. (The concentration of the compound of zinc)/(the concentration of the compound of gallium) at the position P11 is higher than (the concentration of the compound of zinc)/(the concentration of the compound of gallium) at the position P12. (The concentration of zinc)/(the concentration of gallium) at the position P11 is higher than (the concentration of zinc)/(the concentration of gallium) at the position P12.

The position P12 thus configured to be in the zinc-poor state can facilitate crystallizing the oxide semiconductor layer 70 near the opening 245c. Oxygen in the oxide semiconductor layer 70 is stabilized, and the transfer of oxygen between the oxide semiconductor layer 70 and the upper electrode 50 can be suppressed. Therefore, the threshold voltage of the field-effect transistor 40 can be stabilized.

In the present embodiment, the concentration of the compound of zinc is equal to or larger than the concentration of the compound of indium and the concentration of the compound of gallium. The oxide semiconductor layer 70 can thereby be rapidly polished.

The concentration of the compound of zinc may be smaller than the concentration of the compound of indium and the concentration of the compound of gallium. The corrosion of the oxide semiconductor layer 70 can thereby be suppressed.

The partial dissolution solution configured to have potential and pH that dissolve the first substance and dissolve neither the second substance nor the third substance is described above, though the partial dissolution solution is not limited thereto. The partial dissolution solution may be configured to have potential and pH that dissolve the first substance, do not dissolve the second substance, and dissolve the third substance.

Specifically, a hatched region R3 is an overlapping region of redox potential Eh and pH ranges in which zinc is soluble in water, redox potential Eh and pH ranges in which indium is soluble in water, and redox potential Eh and pH ranges in which gallium is insoluble in water (see FIGS. 13 to 15).

More specifically, the region R3 is an overlapping region of the region S(Zn), the region S(In), and the region I(Ga). The partial dissolution solution may have redox potential Eh and pH included in the region R3.

In this case, (the concentration of the compound of indium)/(the concentration of the compound of gallium) at the position P11 is higher than (the concentration of the compound of indium)/(the concentration of the compound of gallium) at the position P12. (The concentration of indium)/(the concentration of gallium) at the position P11 is higher than (the concentration of indium)/(the concentration of gallium) at the position P12.

(The concentration of the compound of zinc)/(the concentration of the compound of gallium) at the position P11 is higher than (the concentration of the compound of zinc)/(the concentration of the compound of gallium) at the position P12. (The concentration of zinc)/(the concentration of gallium) at the position P11 is higher than (the concentration of zinc)/(the concentration of gallium) at the position P12.

The position P12 thus configured to be relatively rich in gallium compared with the position P11 can stabilize oxygen near the opening 245c. The transfer of oxygen between the oxide semiconductor layer 70 and the upper electrode 50 can thereby be suppressed. Therefore, the threshold voltage of the field-effect transistor 40 can be stabilized.

The partial dissolution solution may have redox potential Eh and pH included in the region R4, the region R3, or the region R5. The partial dissolution solution configured to have potential and pH that dissolve the first substance and dissolve neither the second substance nor the third substance is described above, though the partial dissolution solution is not limited thereto. The partial dissolution solution may be configured to have potential and pH that dissolve the first substance, do not dissolve the third substance, and dissolve the second substance.

Specifically, a hatched region R5 is an overlapping region of redox potential Eh and pH ranges in which zinc is soluble in water, redox potential Eh and pH ranges in which indium is insoluble in water, and redox potential Eh and pH ranges in which gallium is soluble in water (see FIGS. 13 to 15).

More specifically, the region R5 is an overlapping region of the region S(Zn), the region I(In), and the region S(Ga). The partial dissolution solution may have redox potential Eh and pH included in the region R5.

In this case, (the concentration of the compound of gallium)/(the concentration of the compound of indium) at the position P11 is higher than (the concentration of the compound of gallium)/(the concentration of the compound of indium) at the position P12. (The concentration of gallium)/(the concentration of indium) at the position P11 is higher than (the concentration of gallium)/(the concentration of indium) at the position P12.

(The concentration of the compound of zinc)/(the concentration of the compound of indium) at the position P11 is higher than (the concentration of the compound of zinc)/(the concentration of the compound of indium) at the position P12. (The concentration of zinc)/(the concentration of indium) at the position P11 is higher than (the concentration of zinc)/(the concentration of indium) at the position P12.

The position P12 thus configured to be relatively rich in indium compared with the position P11 can increase a carrier of the oxide semiconductor layer 70 near the contact interface between the oxide semiconductor layer 70 and the upper electrode 50. This can reduce the contact resistance between the oxide semiconductor layer 70 and the upper electrode 50.

In the example described above, the concentration of the compound of zinc and the concentration of the compound of indium are equal to or larger than the concentration of the compound of gallium. The oxide semiconductor layer 70 can thereby be rapidly polished.

The concentration of the compound of zinc may be smaller than the concentration of the compound of indium and the concentration of the compound of gallium. The corrosion of the oxide semiconductor layer 70 can thereby be suppressed.

In both the first embodiment and the second embodiment, the polishing object configured to comprise oxygen is described, though the polishing object is not limited thereto. The polishing method according to the present disclosure may be configured such that at least one of the first substance and the second substance comprises no oxygen as long as the polishing object has a mixture of the first substance and the second substance having chemical composition different from the chemical composition of the first substance. Specifically, at least one of the first substance and the second substance may be a simple substance or a compound other than oxide, such as a metal simple substance, an intermetallic compound or alloy, metal nitride, metal sulfide, metal carbide, or metal oxynitride.

Specifically, the first substance may be configured to comprise at least one of boron (B), carbon (C), nitrogen (N), fluorine (F), phosphorus (P), and sulfur(S) instead of oxygen or together with oxygen.

The second substance may be configured to comprise at least one of boron (B), carbon (C), nitrogen (N), fluorine (F), phosphorus (P), and sulfur(S) instead of oxygen or together with oxygen.

The first substance may be configured to comprise at least one of indium (In), gallium (Ga), zinc (Zn), aluminum (Al), tin (Sn), titanium (Ti), silicon (Si), germanium (Ge), hafnium (Hf), zirconium (Zr), yttrium (Y), vanadium (V), tungsten (W), tantalum (Ta), molybdenum (Mo), chromium (Cr), nickel (Ni), niobium (Nb), copper (Cu), cobalt (Co), gold (Au), silver (Ag), platinum (Pt), palladium (Pd), ruthenium (Ru), iridium (Ir), arsenic (As), antimony (Sb), tellurium (Te), selenium (Se), bismuth (Bi), scandium (Sc), magnesium (Mg), and iron (Fe) instead of oxygen or together with oxygen.

The second substance may be configured to comprise at least one of indium (In), gallium (Ga), zinc (Zn), aluminum (Al), tin (Sn), titanium (Ti), silicon (Si), germanium (Ge), hafnium (Hf), zirconium (Zr), yttrium (Y), vanadium (V), tungsten (W), tantalum (Ta), molybdenum (Mo), chromium (Cr), nickel (Ni), niobium (Nb), copper (Cu), cobalt (Co), gold (Au), silver (Ag), platinum (Pt), palladium (Pd), ruthenium (Ru), iridium (Ir), arsenic (As), antimony (Sb), tellurium (Te), selenium (Se), bismuth (Bi), scandium (Sc), magnesium (Mg), and iron (Fe) instead of oxygen or together with oxygen.

In relation to the above description about the embodiments, the following additional remarks are further disclosed.

### Additional Remarks

(a) A polishing method comprising:
   supplying an abrasive to a semiconductor substrate provided with a polishing object with a mixture of a first substance and a second substance containing a plurality of atoms connected through a chemical bond in a form different from that of a chemical bond that connects a plurality of atoms contained in the first substance; and
   polishing the polishing object using the abrasive, wherein
   the abrasive comprises:
      a partial dissolution solution having potential and pH that dissolve the first substance and do not dissolve the second substance; and
      abrasive grains dispersed in the partial dissolution solution.
(b) A polishing method comprising:
   supplying an abrasive to a semiconductor substrate provided with a polishing object with a mixture of a first substance which is a compound or a simple substance and a second substance which is a compound or a simple substance different from the first substance; and
   polishing the polishing object using the abrasive, wherein
   the abrasive comprises:
      a partial dissolution solution having potential and pH that dissolve the first substance and do not dissolve the second substance; and
      abrasive grains dispersed in the partial dissolution solution.
(c) The polishing method, wherein the first substance comprises oxygen.
(d) The polishing method, wherein the second substance comprises oxygen.
(e) The polishing method, wherein the first substance comprises a first metal element.
(f) The polishing method, wherein
the second substance comprises a second metal element.

Hereinbefore, the present embodiment is described with reference to specific examples. However, the present disclosure is not limited by these specific examples. These specific examples to which a design change has been appropriately added by those skilled in the art are also encompassed by the scope of the present disclosure as long the resulting examples have the features of the present disclosure. Each component possessed by each of the specific examples mentioned above, and its arrangement, condition, shape, and the like are not limited to those listed herein and can be appropriately changed or modified. A combination of each component possessed by each of the specific examples mentioned above can be appropriately changed unless technical contradiction occurs.

1. A polishing method comprising:
supplying an abrasive to a semiconductor substrate provided with a polishing object with a mixture of a first substance and a second substance having chemical composition different from chemical composition of the first substance; and
polishing the polishing object using the abrasive, wherein
the abrasive comprises:
a partial dissolution solution having redox potential and pH that dissolve the first substance and do not dissolve the second substance; and
abrasive grains dispersed in the partial dissolution solution.

2. The polishing method according to claim 1, wherein
the partial dissolution solution comprises an oxidizing agent having an oxoacid compound, peroxide, a bromine compound, an iron compound, ozone, silver salt, a carboxylic acid compound, acetyl acetonate, or phthalate.

3. The polishing method according to claim 1, wherein
the partial dissolution solution comprises a reducing agent having an organic acidic compound, a saccharide, hydrogen peroxide, a reduced sulfur compound, or a hydrazine compound.

4. The polishing method according to claim 1, wherein
the partial dissolution solution comprises a surfactant having a polyoxyethylene group or a polyoxypropylene group.

5. The polishing method according to claim 1, wherein
the partial dissolution solution comprises a surfactant having mono-long-chain alkyl-type quaternary ammonium salt, di-long-chain alkyl-type quaternary ammonium salt, long-chain alkyltrimethylammonium salt, long-chain alkylpyridinium salt, long-chain alkylimidazolinium salt, long-chain alkyldimethylbenzylammonium salt, or a cationic polymer.

6. The polishing method according to claim 1, wherein
the partial dissolution solution comprises a surfactant having a sulfonic acid group or a sulfoxyl group.

7. The polishing method according to claim 1, wherein
the partial dissolution solution comprises a pH adjuster having nitric acid, sulfuric acid, hydrochloric acid, phosphoric acid, tartaric acid, succinic acid, citric acid, malic acid, malonic acid, fatty acid, polyvalent carboxylic acid, potassium hydroxide, sodium hydroxide, ammonium hydroxide, ammonia, tetraethylammonium hydroxide, ethylenediamine, an organic quaternary ammonium hydroxide compound, organic amine, piperazine, polyethylenimine, or modified polyethylenimine.

8. The polishing method according to claim 1, wherein
the first substance comprises at least one of oxygen, boron, carbon, nitrogen, fluorine, phosphorus, and sulfur.

9. The polishing method according to claim 1, wherein
the second substance comprises at least one of oxygen, boron, carbon, nitrogen, fluorine, phosphorus, and sulfur.

10. The polishing method according to claim 1, wherein
the first substance comprises oxygen and at least one of indium, gallium, zinc, aluminum, tin, titanium, silicon, germanium, hafnium, zirconium, yttrium, vanadium, tungsten, tantalum, molybdenum, chromium, nickel, niobium, copper, cobalt, gold, silver, platinum, palladium, ruthenium, iridium, boron, arsenic, antimony, tellurium, selenium, bismuth, scandium, magnesium, and iron.

11. The polishing method according to claim 1, wherein
the second substance comprises oxygen and at least one of indium, gallium, zinc, aluminum, tin, titanium, silicon, germanium, hafnium, zirconium, yttrium, vanadium, tungsten, tantalum, molybdenum, chromium, nickel, niobium, copper, cobalt, gold, silver, platinum, palladium, ruthenium, iridium, boron, arsenic, antimony, tellurium, selenium, bismuth, scandium, magnesium, and iron.

12. The polishing method according to claim 1, wherein
a concentration of the first substance is equal to or larger than a concentration of the second substance.

13. The polishing method according to claim 1, wherein
a concentration of the first substance is smaller than a concentration of the second substance.

14. The polishing method according to claim 1, wherein
the polishing method comprises:
forming a protective layer on the semiconductor substrate;
forming an open depression in a surface of the protective layer; and
forming the polishing object so as to cover the surface while filling the depression, wherein
when the polishing object is polished using the abrasive, the polishing object is polished until the protective layer is exposed.

15. The polishing method according to claim 1, wherein
the first substance comprises indium, and
the second substance comprises tin.

16. The polishing method according to claim 1, wherein
the polishing object is further mixed with a third substance having chemical composition different from the chemical composition of the first substance and the chemical composition of the second substance, and
the partial dissolution solution has redox potential and pH that dissolve the first substance, do not dissolve the second substance, and dissolve the third substance.

17. The polishing method according to claim 1, wherein
the polishing object is further mixed with a third substance having chemical composition different from the chemical composition of the first substance and the chemical composition of the second substance, and
the partial dissolution solution has redox potential and pH that dissolve the first substance, do not dissolve the second substance, and do not dissolve the third substance.

18. An abrasive comprising:
a partial dissolution solution having redox potential and pH that dissolve a first substance and do not dissolve a second substance having chemical composition different from chemical composition of the first substance; and
abrasive grains dispersed in the partial dissolution solution, wherein
the abrasive is used in the polishing of a polishing object with a mixture of the first substance and the second substance.

19. A semiconductor device comprising:
a protective layer disposed on a semiconductor substrate; and
a polishing object with a mixture of a first substance and a second substance having chemical composition different from chemical composition of the first substance, the polishing object being filled into an open depression in a surface of the protective layer, wherein
a ratio of a concentration of the first substance to a concentration of the second substance at a first position contained in the polishing object is higher than the ratio at a second position closer to an opening of the depression than the first position.
